(19) United States
(12) Patent Application Publication
(10) Pub. No.: US 2008/0251857 A1
(43) Pub. Date: Oct. 16, 2008

(54) Semiconductor Device with Improved Contact Pad and Method for Fabrication Thereof

(75) Inventor: Adam Brown, Cheshire (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/088,004

(22) PCT Filed: Sep. 28, 2006
(86) PCT No.: PCT/IB2006/053535

§ 371 Date: Mar. 25, 2008

(30) Foreign Application Priority Data
Sep. 29, 2005 (EP) 05109031.4
Sep. 28, 2006 (IB) PCT/IB2006/053535

(51) Int. Cl. H01L 29/78; H01L 21/336

(52) U.S. Cl. 257/382; 438/297; 257/E29.255; 257/E21.409

(57) ABSTRACT

A semiconductor device and method of its manufacture is disclosed. The device comprises an active semiconductor region (1A) comprising one or more conductive gates (11) and a contact region (1 B) remote from the active region (1A), typically comprising a field oxide region (3). An insulating layer (17) overlies the remote contact region (1 B) and at least a part of the active semiconductor region (1A) with one or more contact windows (19a) formed therethrough at locations between the conductive gates (11). A metallisation contact pad (23) overlying the insulating layer (17) is provided in the remote contact region (1 B). The metallisation contact pad (23) is contacted with a polysilicon contact strip (15) underlying the insulating layer (17) by a conductive pattern of a plurality of filled contact windows (19b) extending across a substantial part of the area of the contact pad (23). In a preferred embodiment, the pattern is a series of filled parallel trenches.

The present invention relates to metallisation contacts in semiconductor devices. The present invention is particularly, but not exclusively, concerned with providing improved gate contacts in trench-gate and DMOS power semiconductor devices.

In trench-gate power semiconductor devices, such as trench MOSFETs, the size of the contact window to the active silicon (i.e. the source contact), reduces with increased trench density. In particular, as trench width and trench spacing reduces to increase device density, the size of the contact window to the source must correspondingly reduce. As a result of this reduced size, the contact resistance of aluminium contacts formed in the contact window to the active silicon undesirably increases. A similar problem arises with DMOS power semiconductor devices. To address this problem of increased contact resistance, it is known to deposit one or more contact/barrier layers in the contact window, prior to forming the aluminium metallisation, to reduce the contact resistance. For example, a contact layer may be formed by blanket depositing a layer of titanium over an insulator layer which overlies the active substrate and in the contact window formed through the insulator layer prior to forming the aluminium contact. A barrier layer of titanium nitride is formed over the titanium layer. A silicidation anneal is then performed to convert the titanium contact layer to titanium silicide, which has very low contact resistance with the active silicon.

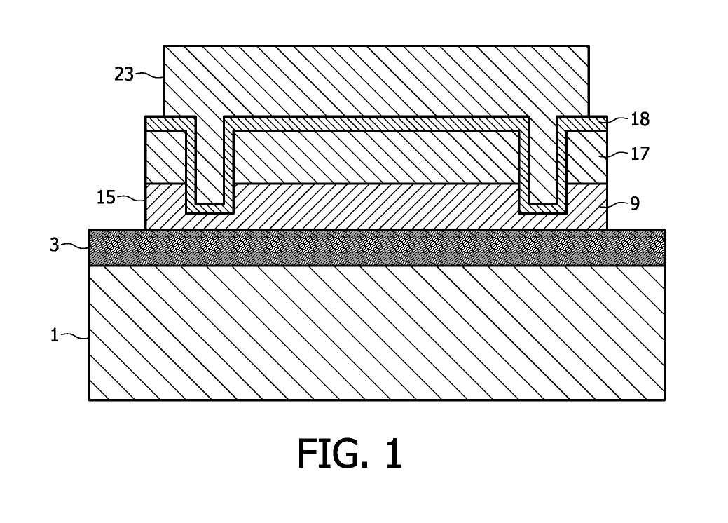

Whilst the use of contact/barrier layers has been found to improve the reliability of source contacts, by reducing contact resistance of the aluminium source electrode to the active silicon, it has been found that the presence of such contact/barrier layers in the region of the gate contact pad is problematic. This problem is described with reference to FIG. 1.

FIG. 1 shows a schematic cross sectional view of a typical prior art aluminium gate contact of a trench MOSFET device, which is typically provided in a field oxide region remote from the active silicon regions on a semiconductor (e.g. silicon) substrate 1. A doped polysilicon strip (not shown), which contacts the trench gates in the active silicon regions, extends up to a polysilicon gate contact pad 9 which overlies the field oxide 3 in the remote gate contact region and is insulated by an overlying TEOS (silicon dioxide) layer 17. A contact ring extending around the edge of the boundary defining the gate contact pad extends through the TEOS layer 17 and into the polysilicon contact pad 9. The contact ring is lined with contact/barrier layers 18 comprising titanium silicide and titanium nitride and filled with aluminium, which extends over the contact/barrier layers 18 to form the aluminium gate contact pad 23. Typically, the gate contact is formed by etching the contact ring in the TEOS 17 concurrently with forming source contact windows in the active region. A titanium/titanium nitride layer is subsequently formed over the TEOS layer 17, in the gate contact ring and in the source contact windows, and annealed to convert the titanium to titanium silicide to provide improved contact resistance of the source contact as described above. The aluminium is subsequently formed and etched to complete the gate contact pad, as shown in FIG. 1.

It has been found the titanium nitride barrier layer forming part of the gate contact exhibits poor adhesion to the underlying TEOS layer, and peeling of the titanium nitride and thus the aluminium of the gate bond pad from the underlying layers may occur, leading to loss of gate contact and consequential device failure.

Generally, the present invention aims to provide improved mechanical and electrical contact of a metallisation contact pad through an insulating layer to an underlying contact strip.

The present invention further seeks to provide improved adhesion of a metallisation contact pad and/or a contact layer to one or more underlying layers. For example, if the contact pad is a gate contact pad of a power semiconductor device (Trench MOSFET or lateral DMOS) having a contact comprising a contact layer such as titanium nitride, the present invention aims to improve adhesion of the contact, and in particular the titanium nitride, to an underlying insulating layer and polysilicon contact strip, thereby retaining the benefit of improved contact resistance of the source contacts due to the presence of the contact layer.

In accordance with a first aspect, the present invention provides a semiconductor device, comprising: an active semiconductor region comprising one or more conductive gates; a contact region remote from the active region; an insulating layer overlying the remote contact region and at least a part of the active semiconductor region with one or more contact windows formed therethrough at locations between the conductive gates; a metallisation contact pad overlying the insulating layer in the remote contact region; wherein the metallisation contact pad is contacted with a contact strip underlying the insulating layer by a conductive pattern comprising a plurality of filled contact windows extending through the insulating layer and across a substantial part of the area of the contact pad.

Since the conductive pattern extends across a substantial part of the contact pad area, there is an increased surface area in contact with the contact strip, thus providing improved mechanical and electrical contact between the metallisation contact pad and the underlying layers.

Moreover, in the case of the conductive pattern including a barrier or contact layer comprising a material having poor adhesion to the insulating layer (as is the case with a titanium nitride barrier layer and TEOS insulating layer), the pattern provides an increase in surface area of the barrier or contact layer in contact with the (typically polysilicon) contact strip, with which it has good adhesion, thereby improving the overall adhesion of the metallisation contact pad.

Preferably the conductive pattern extends across at least a third of the area of the major surface of the metallisation contact pad, and more preferably the pattern extends across more that two thirds of the surface area.

In one embodiment, the conductive pattern extends across substantially the entire area of the metallisation contact pad.

In some embodiments, the conductive pattern comprises a plurality of substantially parallel contact trenches. Ideally the pitch and geometry (e.g. width) of the trenches corresponds substantially to the pitch and geometry of the contact windows between the gates in the active region. This ensures that, during formation thereof, completion of the etching of the contact windows in the active and contact regions is substantially concurrent, and hence the reliability of the etched contacts.

In other embodiments the pattern may be provided as concentric rings or arcs, concentric rectangles or orthogonally arranged trenches.

Preferably the surface area occupied by the conductive pattern is between 5% and 50% of the total area of the metallisation contact pad, and more preferably about 10%.

By increasing the proportion of the area of the contact pad occupied by the conductive pattern of filled contact windows, in comparison with the conventional single contact ring, a greater amount of material forming a contact/barrier layer, provided in the contact windows prior to filling with metallisation material (e.g. aluminium), contacts the contact strip which provides good adhesion in comparison to the insulating layer. Thus, there is a reduced risk of the contact/barrier layer (e.g. titanium nitride) and thus the metallisation material (e.g. aluminium) peeling from the underlying insulating layer (e.g. TEOS layer) due to poor adhesion between the contact/barrier layer and the insulating layer.

In accordance with a second aspect, the present invention provides a semiconductor device, comprising: an active semiconductor region comprising one or more conductive gates; a contact region remote from the active region; an insulating layer overlying the remote contact region and at least a part of the active semiconductor region with one or more contact windows formed therethrough at locations between the conductive gates; a conductive contact pad overlying the insulating layer in the remote contact region; wherein the contact pad is contacted with a contact strip underlying the insulating layer by a conductive pattern of filled contact windows, the contact windows forming the conductive pattern comprising a plurality of substantially parallel or concentric contact trenches.

Ideally, the dimensions and/or pitch of the features of the pattern are substantially similar to the dimensions and/or pitch of the one or more contact windows in the active semiconductor region.

In accordance with a third aspect, the present invention provides a method for fabricating a semiconductor device, comprising: defining an active region and a contact region remote from the active region, in a semiconductor substrate; forming a field oxide region over the substrate in the contact region; providing a polysilicon layer over the active region and the field oxide in the contact region; patterning the polysilicon layer to form conductive gates in the active region and a contact strip extending from at least some of the gates to the contact region; forming an insulating layer over the patterned polysilicon layer; forming contact windows through the insulating layer between at least some of the gates in the active region and in a plurality of contact windows the contact region above the contact strip; forming a layer of conductive material in the contact windows and over the insulating layer; patterning the conductive layer to form metallisation contacts in the active region and a gate contact pad in the contact region, wherein the plurality of filled contact windows contacting the gate contact pad to the contact strip extend across a substantial part of the area of the contact pad.

Preferably, the step of forming a layer of conductive material in the contact windows and over the insulating layer comprises forming a contact or barrier layer in the contact windows and over the insulating layer, and forming a layer of metallisation material over the contact or barrier layer.

Other optional features and advantages of the present invention will be apparent from the following description and accompanying claims.

Embodiments of the present invention will now be described, by way of example only, with reference to the accompanying drawings, in which:

FIG. 1 is a cross section through a gate contact of a prior art trench-gate power semiconductor device;

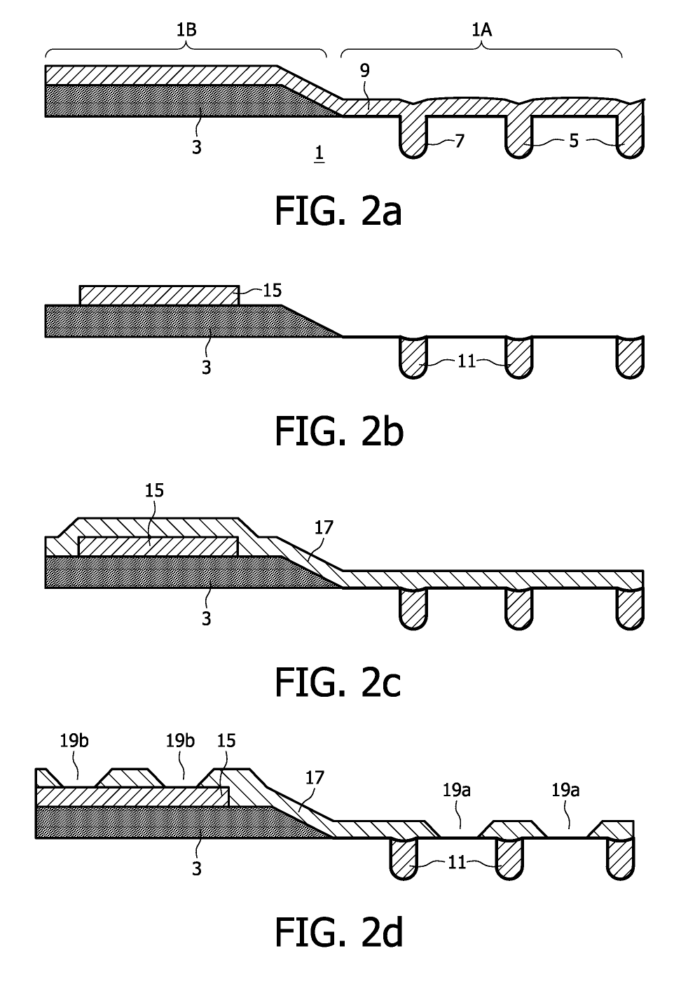

FIG. 2a to 2e illustrate steps for fabricating a Trench-gate power semiconductor device in accordance with a first embodiment of the present invention;

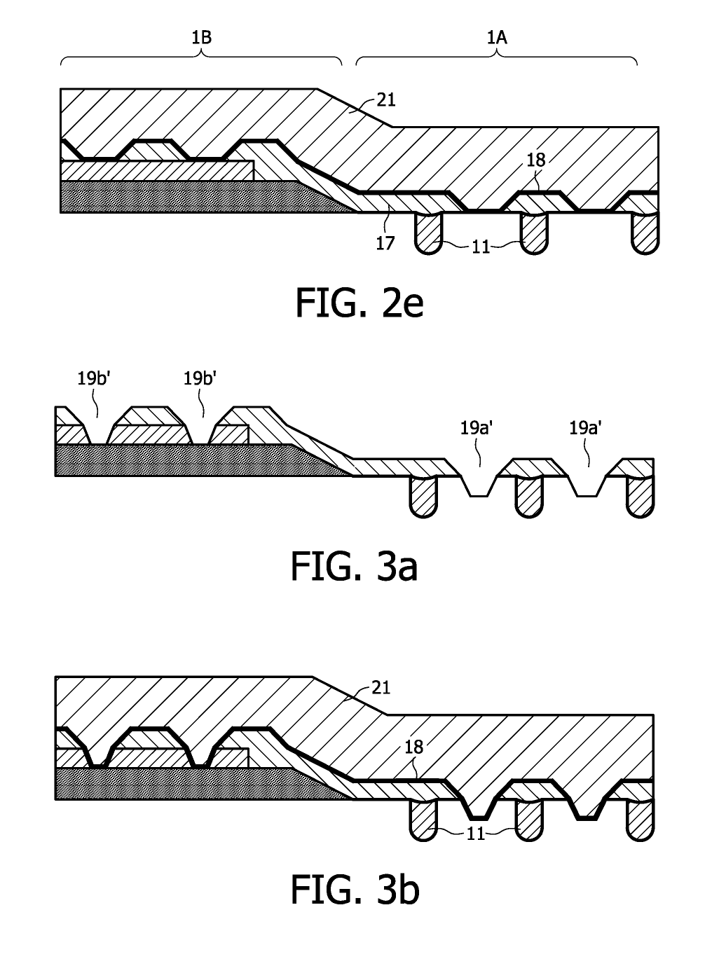

FIGS. 3a and 3b illustrate steps for fabricating a Trench semiconductor device in accordance with a second embodiment of the present invention, which steps replace the step of FIG. 2e of the first embodiment of the present invention;

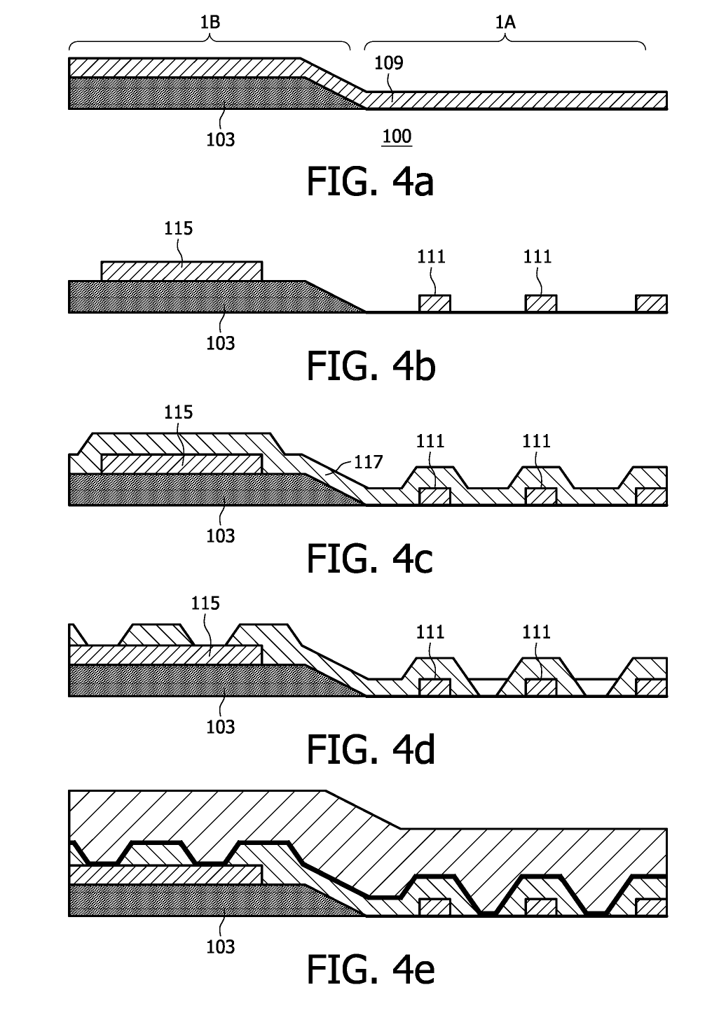

FIGS. 4a to 4e illustrate steps for fabricating a DMOS power semiconductor device in accordance with a third embodiment of the present invention;

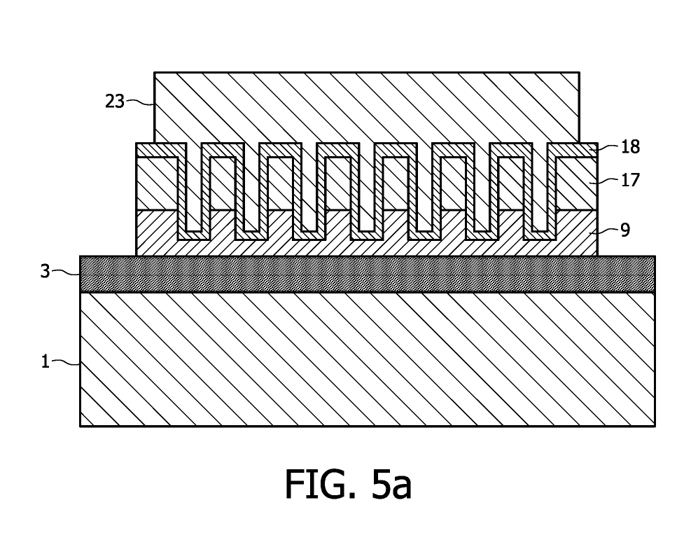

FIG. 5a is a schematic cross section through, and FIG. 5b is a schematic plan view of, a gate contact pad of a power semiconductor device in accordance with an embodiment of the present invention, and

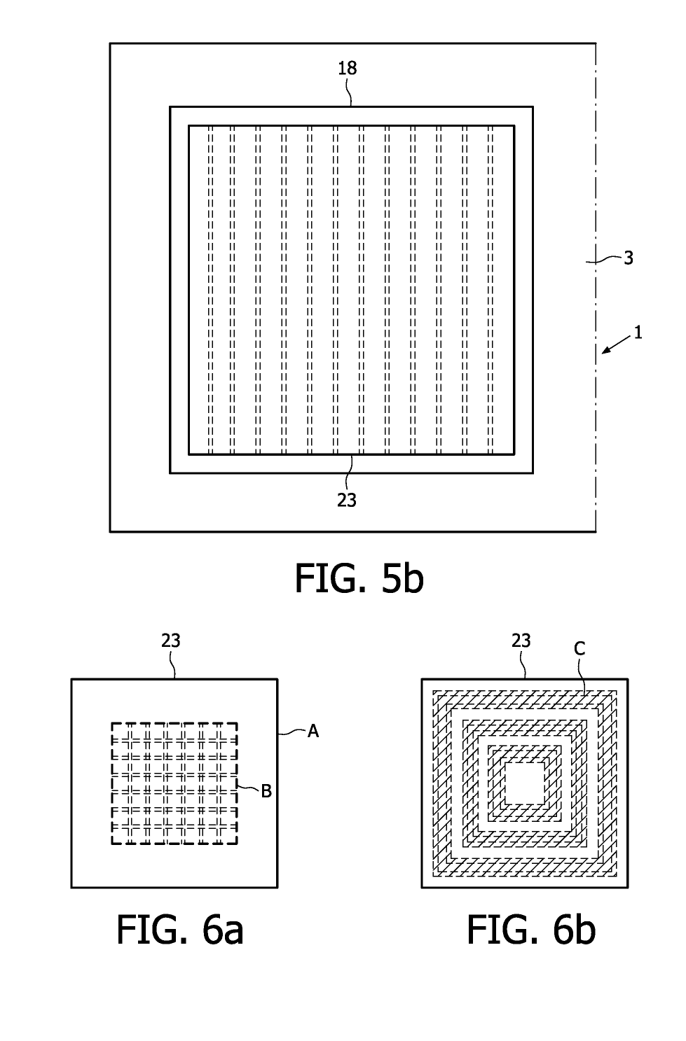

FIGS. 6a and 6b are schematic plan views of a gate contact pad in accordance with alternative embodiments of the present invention

The drawings are for illustrative purposes only, and are not to scale. Similar elements in the drawings have been accorded like reference numerals.

FIGS. 2a to 2e illustrate the steps for fabricating a Trench-gate power semiconductor device in accordance with a first embodiment of the present invention.

As shown generally in FIG. 2a, the device comprises an active semiconductor region 1A and a remote, contact region 1B of a semiconductor substrate 1 (e.g. monocrystalline silicon substrate). The active region 1A comprises a plurality of trench-gate MOSFETs formed in the substrate 1 and the remote contact region is a peripheral field oxide region.

Prior to the process stage illustrated in FIG. 2a, a thick field oxide layer 3 is grown in the contact region 1B, trenches 5 etched in the active region 1A, gate dielectric 7 formed 9 e.g. by growing oxide) in the trenches 5, and polysilicon 9 deposited in the trenches 5 and over the field oxide layer 3 and doped with a suitable dopant.

Subsequently, as shown in FIG. 2b, the polysilicon 9 is etched. In particular, the polysilicon 9 in the active region 1A is etched back to the substrate 1 to leave the trenches 5 filled to form polysilicon gates 11, and the polysilicon in the contact region 1B is etched using a suitable etch mask to leave a relatively large polysilicon gate contact pad 15. It will be appreciated that polysilicon strips (not shown) connecting the polysilicon gates 11 to the polysilicon gate contact pad 15 are also formed integrally with the polysilicon contact pad 15 using the etch mask (not shown). Thus, the polysilicon contact pad 15 is a terminal part of a polysilicon contact strip, and, accordingly, the terms contact pad and contact strip are used synonymously.

An insulating layer 17 is formed over the active 1A and contact 1B regions as shown in FIG. 2c. The insulating layer 17 may comprise any suitable insulating material such as silicon dioxide, TEOS, silicon nitride, an insulating stack such as ONO, a polymeric insulator etc. The insulating layer 17 may be blanket deposited in any conventional or known manner.

The insulating layer 17 is next patterned and etched using conventional techniques to form contact windows 19a and 19b. In particular, and as illustrated in FIG. 2d, contact vias are etched through the insulating layer 17 in the active region 1A at regularly spaced intervals between at least some, and typically all, of the trench gates 11, to provide contact windows 19a to the underlying substrate for the formation of source contacts. In addition, a contact pattern of trench-shaped vias is etched through the insulating layer 17 in the contact region 1B at corresponding regularly spaced intervals to provide contact windows 19b to the polysilicon gate contact pad 15. The etching of the insulating layer 17 stops at the surface of the substrate 1 as shown in FIG. 2d.

It will be appreciated that in embodiments, the pitch and structure of the contact windows 19a in the active region 1A and the contact windows 19b in the contact region 1B are substantially the same. This has the advantage that etching of the contact windows 19a through the insulating layer 17 completes substantially concurrently with the etching of the contact windows 19b, due to the similar geometry of the etched features and the similar proportion of etched insulating material in the active 1A and remote 1B regions.

In the illustrated embodiment a barrier or contact layer 18 is formed on the insulating layer 17 and in the contact windows 19a in the active region 1A and in the contact windows 19b in the contact region 1B. For example, a continuous contact layer comprising a double layer of titanium and titanium nitride may be used. In particular, and in accordance with conventional techniques, a continuous layer of a silicidation metal, such as titanium, may be formed as a contact layer over the insulating layer 17, in the gate contact windows 19b and in the source contact windows 19a, and a barrier layer of titanium nitride formed over the titanium layer. Subsequently the structure is heated to convert the titanium layer to titanium silicide (not shown) at the bottom of the source contact windows 19a, thereby improving contact resistance of the source contacts. The barrier layer 18 of titanium nitride remains in the final structure as shown in FIG. 2e. It will be appreciated that, in other embodiments, barrier or contact layers may be formed of other materials such as other silicidation metals, titanium, tungsten, cobalt, nickel, tantalum, molybdenum, platinum etc. Alternatively in some embodiments, barrier or contact layer 18 may be omitted altogether.

A metallisation layer 21 of conductive material is then deposited over the complete structure to form contacts as shown in FIG. 2e. Typically the conductive material comprises a metal such as aluminium.

Subsequently, the metallisation 21 is patterned to form a contact pad 23 having a relatively large surface area, as shown in FIG. 5, as well as other conductive metallisation structures. Advantageously, since the contact pad 23 is contacted to the underlying polysilicon gate contact pad 15 by a contact pattern with a plurality of contacts having a relatively large surface area in mechanical and electrical contact with the polysilicon and since the contact pattern extends over a significant proportion of the contact pad area, the risk of peeling of the metallisation material and/or any contact or barrier layers from the TEOS, due to poor adhesion thereto, is minimised.

In an alternative embodiment, after the step of etching the insulating layer 17 to the substrate, as shown in FIG. 2d, the silicon in the active area 1A is further etched, as well known in the art, to form source moat contacts 19a′ as shown in FIG. 3a. This additional etching step to form the moat contacts may also etch the polysilicon contact pad 15 in the contact region 1B. Thus, contact windows 19b′ may be formed, extending into the polysilicon 15, as far as, but preferably not into, the field oxide 3. Thereafter, a contact or barrier layer and the conductive layer for the metallisation 23 are formed over the structure as described above in relation to FIG. 2e, as shown in FIG. 3b. The moat contacts 19′ in the contact region 1B further increase the surface area of the contact layer 18 in contact with the polysilicon 15, thereby further assisting adhesion.

As the skilled person will appreciate, the present invention may also be used in semiconductor device configurations other than Trench MOSFET devices. For example, the invention may be used in a lateral power DMOS device as described below with reference to FIGS. 4a to 4e, which are similar to FIGS. 2a to 2e and in which similar reference numerals designate similar features.

In the device of FIGS. 4a to 4e, the active region 1A comprises a plurality of DMOS gates 111 formed on the substrate 100 and the remote contact region 1B is a peripheral field oxide region.

Prior to the process stage illustrated in FIG. 4a, a thin gate dielectric layer 107 is formed over the active region 1A and a thick field oxide layer 103 is grown in the contact region 1B. Then, as shown in FIG. 4a, a layer of polysilicon 109 is blanket deposited over the active region 1A and the remote contact region 1B and doped.

Subsequently, as shown in FIG. 4b, the polysilicon 109 is etched. In particular, the layer of polysilicon 109 is patterned using conventional patterning techniques such as photolithography and etched to form polysilicon DMOS gates 111 in the active region 1A, and a relatively large polysilicon gate contact pad 115 in the contact region 1B. It will be appreciated that polysilicon strips (not shown) connecting the polysilicon gates 111 to the polysilicon gate contact pad 115 may be integrally formed at this stage, and that contact pad 115 forms the terminal end of such a contact strip.

An insulating layer 117 is formed over the active 1A and contact 1B regions as shown in FIG. 4c. The insulating layer 117 may comprise any suitable insulating material such as silicon dioxide, TEOS, silicon nitride, an insulating stack such as ONO, a polymeric insulator etc. The insulating layer may be blanket deposited in any conventional or known manner.

The insulating layer 117 is next patterned and etched using conventional techniques to form contact windows 19a and 19b. In particular, and as illustrated in FIG. 4d, contact vias are etched through the insulating layer 117 in the active region 1A at regularly spaced intervals between at least some, and, as illustrated, typically all, of the DMOS gates 111, to provide contact windows 119a to the underlying substrate for the formation of source contacts. In addition, a contact pattern of trench-shaped vias is etched through the insulating layer 117 in the contact region 1B, the vias at corresponding regularly spaced intervals to provide contact windows 119b to the polysilicon gate contact pad 115. The etching of the insulating layer 117 stops at the surface of the substrate 100 as shown in FIG. 4d.

It will be appreciated that in embodiments, the pitch and form (e.g. geometry) of the contact windows 19a in the active region 1A and of the contact windows 19b in the contact region 1B are substantially the same.

In the illustrated embodiment a barrier or contact layer 118 is formed on the insulating layer 117 and in the contact windows 119a in the active region 1A and in the contact windows 119b in the contact region 1B. For example, and in accordance with conventional techniques, a layer of silicidation metal such as titanium may be formed as a contact layer over the insulating layer 117, in the gate contact windows 119b and in the source contact windows 119a, and a barrier layer of titanium nitride formed over the titanium layer. Subsequently the structure is heated to convert the titanium layer to titanium silicide (not shown) at the bottom of the source contact windows 119a, thereby improving contact resistance of the source contacts, leaving the titanium nitride barrier layer 118. It will be appreciated that, in other embodiments, barrier or contact layers 118 may be formed of other materials, or indeed, the layer 118 may be omitted altogether.

A metallisation layer 121 of conductive material is then deposited over the complete structure to form contacts as shown in FIG. 4e. Typically the conductive material comprises a metal such as aluminium.

FIGS. 5a and 5b show a gate contact in accordance with an embodiment of the present invention. In the illustrated example, a barrier layer of titanium nitride 18 is provided over the TEOS insulating layer 17 and in the gate contact windows 19b, which are formed as a series of parallel trenches of similar shape and pitch to the source contact windows 19a. It will be appreciated that the pitch and geometry of the trenches illustrated in FIGS. 5a and 5b are not to scale. Thus, the aluminium contact pad 23 is electrically and mechanically contacted with the underlying polysilicon gate contact pad 15 by a conductive contact pattern of titanium nitride lined, aluminium filled trenches extending across substantially the entire area of the contact pad 23 (see FIG. 5b). As stated above, titanium nitride exhibits poor adhesion to TEOS. However, since the titanium nitride has an increased surface area in contact with polysilicon, with which it has good adhesion, compared with the prior art contact ring as shown in FIG. 1, the adhesion of the contact pad 23 is increased, thereby reducing the risk of peeling of the titanium nitride and overlying aluminium contact pad and consequent device failure.

It will be appreciated that the contact pattern need not be a pattern of parallel filled trenches, but might equally be a series of concentric rings, concentric arcs, concentric rectangles, a pattern of orthogonal trenches or other equivalent patterns. In addition, the contact pattern need not extend across the entire contact pad area. For example, FIG. 6a shows a pattern of orthogonal, lined conductive trenches and FIG. 6b shows a pattern of concentric rectangular trenches, also lined and filled with conductive material. With reference to FIG. 6a, the conductive pattern need not occupy the total area A of the metallisation contact pad 23. Typically, the conductive contact pattern extends across an area B that is at least a third of the total area A of the contact pad, and is preferably at least two thirds of the area A. At the same time the size, geometry and pitch of the features of the pattern are optimised to ensure concurrent etching with the source contact windows. By selecting a contact pattern that occupies at least a third of the contact pad area, it is possible to achieve good adhesion and mechanical and electrical contact to the underlying polysilicon gate contact strip.

In embodiments, the features of the contact pattern, which are formed by etching insulating material as described above, consume an area C (shaded in FIG. 6b) of between 5% and 50% of the total area A of the insulating material defining the major surface of the contact pad 23. In a typical embodiment such as a Trench MOSFET, in which the geometry of the features (e.g. trenches) of the contact pattern are similar to those of the source contact windows, the area C may be in the region of 10% of the total area A defining the metallisation contact pad 23.

The skilled person will appreciate that the present invention may be applied to contact pads other that gate contact pads in power Trench MOSFET or DMOS devices. For example, it may be used in conjunction with the contact pads of TOPFET devices.

From reading the present disclosure, other variations and modifications will be apparent to the skilled person. Such variations and modifications may involve equivalent and other features which are already known in the art, and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The applicant hereby gives notice that new claims may be formulated to such features and/or combinations of such features during the prosecution of the present application or of any further application derived therefrom.

1. A semiconductor device, comprising:
an active semiconductor region comprising one or more conductive gates;
a contact region remote from the active region;
an insulating layer overlying the remote contact region and at least a part of the active semiconductor region with one or more contact windows formed therethrough at locations between the conductive gates;
a conductive contact pad overlying the insulating layer in the remote contact region;
wherein the contact pad is contacted with a contact strip underlying the insulating layer by a conductive pattern comprising a plurality of filled contact windows, the pattern extending across a substantial part of the area of the contact pad.

2. A semiconductor device as claimed in claim 1, wherein the contact windows forming the conductive pattern comprise a plurality of substantially parallel or concentric contact trenches.

3. A semiconductor device, comprising:
an active semiconductor region comprising one or more conductive gates;
a contact region remote from the active region;
an insulating layer overlying the remote contact region and at least a part of the active semiconductor region with one or more contact windows formed therethrough at locations between the conductive gates;
a conductive contact pad overlying the insulating layer in the remote contact region;
wherein the contact pad is contacted with a contact strip underlying the insulating layer by a conductive pattern of filled contact windows, the contact windows forming the conductive pattern comprising a plurality of substantially parallel or concentric contact trenches.

4. A semiconductor device as claimed in claim 2, wherein the pitch of the trenches corresponds substantially to the pitch of the contact windows between the gates in the active region.

5. A semiconductor device as claimed in claim 2, wherein the form of the trenches corresponds substantially to the form of the contact windows between the gates in the active region.

6. A semiconductor device as claimed in claim 1, further comprising a contact or barrier layer overlying the insulating layer and in the contact windows.

7. A semiconductor device as claimed in claim 6, wherein the contact or barrier layer comprises a material selected from the group consisting of: titanium; tungsten, cobalt; nickel; tantalum; molybdenum; platinum, and cobalt, and nitrides thereof.

8. A semiconductor device as claimed in claim 1, wherein the insulating later comprises a material selected from the group consisting of: TEOS; silicon dioxide; silicon nitride, and polymeric insulators.

9. A semiconductor device as claimed in claim 1, wherein the contact strip comprises a doped polysilicon strip which contacts at least some of the conductive gates in the active region.

10. A semiconductor device as claimed in claim 1, comprising a power trench MOSFET, a lateral power DMOS or a TOPFET.

11. A semiconductor device as claimed in claim 1, wherein the conductive pattern occupies an area that is at least one third of the total areas of the contact pad.

12. A semiconductor device as claimed in claim 1, wherein the contact windows forming the conductive pattern occupy an area which is between 5% and 50% of the area of the contact pad.

13. A method for fabricating a semiconductor device, comprising:
defining an active region and a contact region remote from the active region, in a semiconductor substrate;
forming a field oxide region over the substrate in the contact region;
providing a polysilicon layer over the active region and the field oxide in the contact region;
patterning the polysilicon layer to form conductive gates in the active region and a contact strip extending from at least some of the gates to the contact region;
forming an insulating layer over the patterned polysilicon layer;
forming contact windows through the insulating layer between at least some of the gates in the active region and a plurality of contact windows in the contact region above the contact strip;
forming a layer of conductive material in the contact windows and over the insulating layer;
patterning the conductive layer to form metallization contacts in the active region and a gate contact pad in the contact region, wherein the plurality of filled contact windows contacting the gate contact pad to the contact strip extend across a substantial part of the area of the contact pad.

14. A method as claimed in claim 13, wherein the step of forming a layer of conductive material in the contact windows and over the insulating layer comprises:
forming a contact layer in the contact windows and over the insulating layer, and
forming a layer of metallization material over the contact layer.

15. A method as claimed in claim 14, wherein the semiconductor substrate comprises silicon, and the contact layer comprises a silicidation metal, and wherein the method further comprises:
after the step of forming a contact layer, annealing the contact layer to form a silicide at the base of the contact windows in the active region.

16. A method as claimed in claim 14, wherein the contact layer comprises a material that exhibits poor adhesion to the material of the insulating layer.

17. A method as claimed in claim 13, wherein the step of forming contact windows comprises etching a pattern of vias in the contact region, wherein the pattern preferably occupies an areas that is at least one third of the total area defining the contact pad.

18. A method as claimed in claim 13, wherein the step of forming contact windows comprises etching a pattern of vias in the contact region, wherein the pattern of vias consumes an area which is between 5% and 50% of the area defining the contact pad.

19. A method as claimed in claim 17, wherein the step of etching a pattern of vias comprises etching vias in the form of parallel or concentric trenches.
